(19) United States
(12) Patent Application Publication
(10) Pub. No.: US 2025/0079279 A1
(43) Pub. Date: Mar. 6, 2025

(54) ELECTRONIC DEVICE INCLUDING A SEMICONDUCTOR PACKAGE AND A METHOD OF MANUFACTURING THE ELECTRONIC DEVICE

(71) Applicant: SAMSUNG ELECTRONICS CO., LTD., SUWON-SI (KR)

(72) Inventors: Geunwoo KIM, Suwon-si (KR); Taehwan KIM, Suwon-si (KR); Taejun KIM, Suwon-si (KR)

(21) Appl. No.: 18/761,415

(22) Filed: Jul. 2, 2024

(30) Foreign Application Priority Data
Sep. 6, 2023 (KR) 10-2023-0118311

(51) Int. Cl. H01L 23/498; H01L 23/00; H01L 23/528; H01L 23/552; H05K 1/11

(52) U.S. Cl. CPC H01L 23/49816; H01L 23/49838; H01L 23/5286; H01L 23/552; H05K 1/111; H01L 24/32; H01L 24/48; H01L 24/73; H01L 2224/32225; H01L 2224/48227; H01L 2224/73265; H01L 2924/1815

(57) ABSTRACT

An electronic device includes a main board; a semiconductor package disposed on the main board and mounted via a plurality of conductive connection members; and an electromagnetic shielding member covering an upper surface and side surfaces of the semiconductor package. The plurality of conductive connection members includes: a plurality of signal connection balls disposed on a middle region of a lower surface of the semiconductor package and having a first diameter; and a plurality of electromagnetic shielding balls spaced apart from each other along an edge of the lower surface of the semiconductor package, the electromagnetic shielding balls surrounding the middle region and having a second diameter smaller than the first diameter.

### CROSS-REFERENCE TO RELATED APPLICATION

This application claims priority under 35 U.S.C. § 119 to Korean Patent Application No. 10-2023-0118311, filed on Sep. 6, 2023, in the Korean Intellectual Property Office (KIPO), the disclosure of which is incorporated by reference herein in its entirety.

### 1. Technical Field

Example embodiments of the inventive concept relate to an electronic device and a method of manufacturing the electronic device. More particularly, example embodiments of the inventive concept relate to an electronic device including a semiconductor package and a method of manufacturing the same.

### 2. Description of the Related Art

Semiconductor packages may include an electromagnetic wave shield. For example, an electromagnetic wave shield may be formed on at least one side of a semiconductor package to shield electromagnetic waves emitted from the semiconductor package. When the semiconductor package is mounted on a main board, if there is no free space to form an electromagnetic wave shield in a peripheral region on a bottom surface of the semiconductor package, the semiconductor package may not be fully shielded.

### SUMMARY

Example embodiments of the inventive concept provide an electronic device having an electromagnetic wave shielding structure that can block electromagnetic wave emission.

Example embodiments of the inventive concept provide a method of manufacturing the electronic device.

According to example embodiments, an electronic device includes a main board; a semiconductor package disposed on the main board and mounted via a plurality of conductive connection members; and an electromagnetic shielding member covering an upper surface and side surfaces of the semiconductor package. The plurality of conductive connection members includes: a plurality of signal connection balls disposed on a middle region of a lower surface of the semiconductor package and having a first diameter; and a plurality of electromagnetic shielding balls spaced apart from each other along an edge of the lower surface of the semiconductor package, the electromagnetic shielding balls surrounding the middle region and having a second diameter smaller than the first diameter.

According to example embodiments, an electronic device includes a main board having a plurality of signal pads and a plurality of ground pads; a semiconductor package disposed on the main board, the semiconductor package including a package substrate having signal substrate pads disposed in a middle region on a lower surface of the package substrate and ground substrate pads disposed in an edge region surrounding the middle region, a semiconductor chip mounted on an upper surface of the package substrate, and a sealing member covering the semiconductor chip; an electromagnetic shielding member covering an upper surface and side surfaces of the semiconductor package; a plurality of signal connection balls disposed between the plurality of signal pads and the signal substrate pads and having a first diameter; and a plurality of electromagnetic shielding balls disposed between the plurality of ground pads and the ground substrate pads and having a second diameter smaller than the first diameter.

According to example embodiments, an electronic device includes a main board; a semiconductor package disposed on the main board; an electromagnetic shielding member covering an upper surface and side surfaces of the semiconductor package; a plurality of signal connection balls disposed between the main board and the semiconductor package, disposed on a middle region of a lower surface of the semiconductor package, and having a first diameter; and a plurality of electromagnetic shielding balls disposed between the main board and the semiconductor package, spaced apart from each other along an edge of the lower surface of the semiconductor package to surround the middle region, and having a second diameter smaller than the first diameter. The first diameter is 400 μm to 500 μm, and the second diameter is 200 μm to 400 μm. A distance between neighboring electromagnetic shielding balls is 80 μm to 150 μm.

### BRIEF DESCRIPTION OF THE DRAWINGS

FIG. 1 is a cross-sectional view illustrating an electronic device in accordance with example embodiments of the inventive concept.

FIG. 2 is an enlarged cross-sectional view illustrating portion ‘A’ in FIG. 1.

FIG. 3 is a bottom view illustrating a plurality of conductive connection members on a bottom surface of a semiconductor package of the electronic device in FIG. 1.

FIG. 4 is an enlarged bottom view illustrating portion ‘B’ in FIG. 3.

FIGS. 5, 6, 7, 8, 9, 10, 11, 12, 13, 14 and 15 are views illustrating a method of manufacturing an electronic device in accordance with example embodiments of the inventive concept.

FIG. 16 is a cross-sectional view illustrating an electronic device in accordance with example embodiments of the inventive concept.

FIG. 17 is a cross-sectional view illustrating an electronic device in accordance with example embodiments of the inventive concept.

FIG. 18 is a cross-sectional view illustrating an electronic device in accordance with example embodiments of the inventive concept.

FIG. 19 is a bottom view illustrating a plurality of conductive connection members on a bottom surface of a semiconductor package.

### DETAILED DESCRIPTION OF THE EXAMPLE EMBODIMENTS

Hereinafter, example embodiments of the inventive concept will be explained in detail with reference to the accompanying drawings.

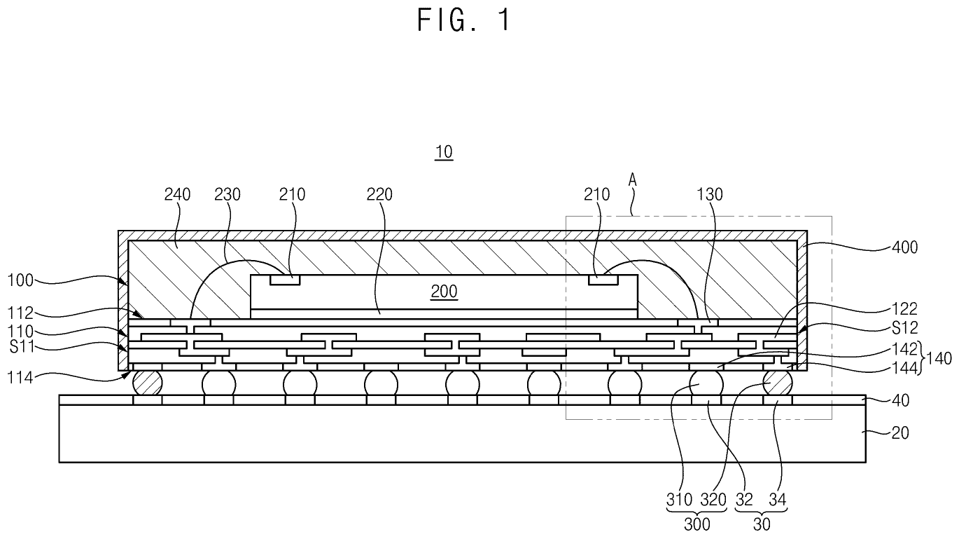

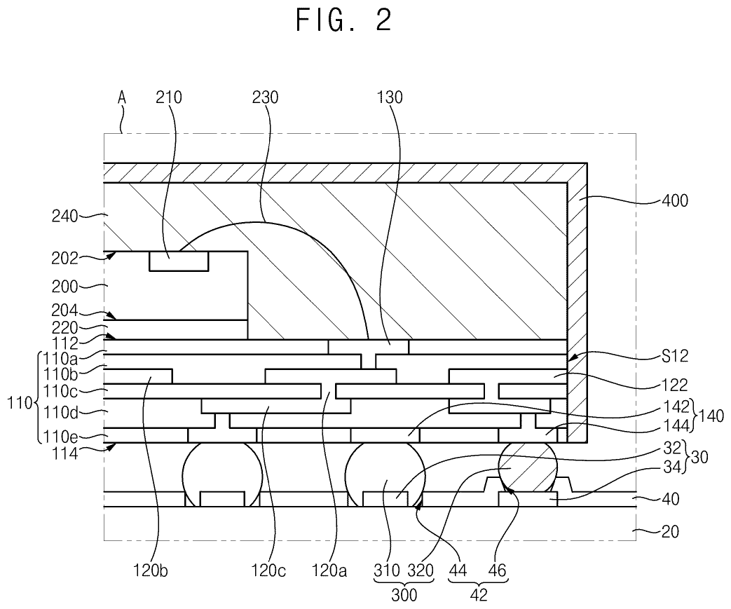

FIG. 1 is a cross-sectional view illustrating an electronic device in accordance with example embodiments. FIG. 2 is an enlarged cross-sectional view illustrating portion ‘A’ in FIG.

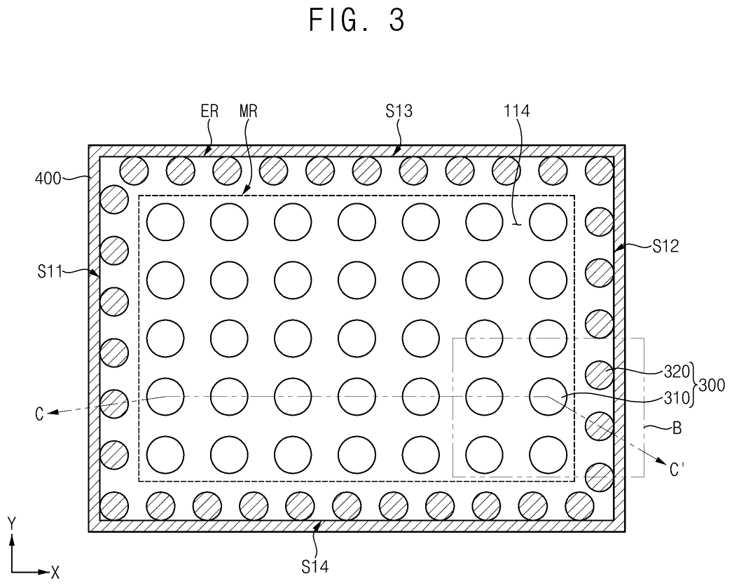

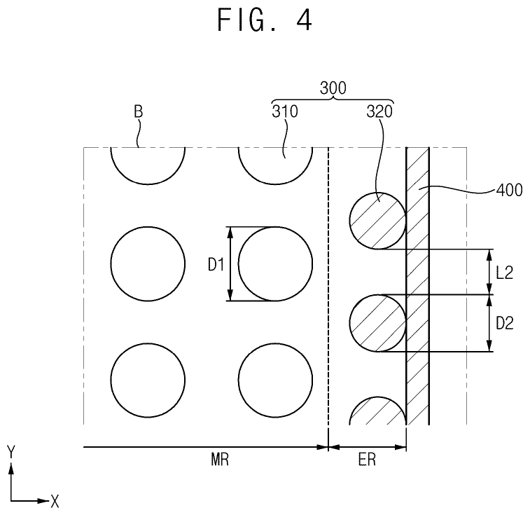

1. FIG. 3 is a bottom view illustrating a plurality of conductive connection members on a bottom surface of a semiconductor package of the electronic device in FIG. 1. FIG. 4 is an enlarged bottom view illustrating portion ‘B’ in FIG. 3. FIG. 1 includes a cross-sectional portion taken along the line C-C′ in FIG. 3.

Referring to FIGS. 1 to 4, an electronic device 10 may include a main board 20, a semiconductor package 100, a plurality of conductive connection members 300, and an electromagnetic shielding member 400. The plurality of conductive connection members 300 may include a plurality of signal connection balls 310 and a plurality of electromagnetic shielding balls 320.

In example embodiments, the main board 20 may be a multilayer circuit board having an upper surface and a lower surface opposite to each other. For example, the main board 20 may be a printed circuit board (PCB). The printed circuit board may be a multilayer circuit board having vias and various circuits therein.

The main board 20 may include a plurality of pads 30 on the upper surface thereof and a protective layer 40 having openings 42 that expose the plurality of pads 30 respectively. For example, the protective layer 40 may be disposed adjacent to the plurality of pads 30 in a lateral direction. The plurality of pads 30 may include a plurality of signal pads 32 and a plurality of ground pads 34. The plurality of pads 30 may be electrically connected to various circuit wires in the main board 20. The ground pads 34 may be electrically connected to a separate ground circuit formed in the main board 20.

In example embodiments, the semiconductor package 100 may include a package substrate 110, at least one semiconductor chip 200 mounted on the package substrate 110, and a sealing member 240 covering the at least one semiconductor chip 200 on the package substrate 110.

As illustrated in FIG. 2, the package substrate 110 may be a multilayer circuit substrate having an upper surface 112 and a lower surface 114 opposite to each other. The package substrate 110 may include a printed circuit board (PCB), a flexible substrate, a tape substrate, etc. The package substrate 110 may include a plurality of stacked insulating layers 110a, 110b, 110c, 110d and 110e and wirings 120a, 120b and 120c respectively provided in the insulating layers. Additionally, the package substrate 110 may include a plurality of upper substrate pads 130 and a plurality of lower substrate pads 140.

For example, the package substrate 110 may include first to fifth insulating layers 110a, 110b, 110c, 110d and 110e sequentially stacked. The first insulating layer 110a may be an upper cover insulating layer, the second insulating layer 110b may be an upper insulating layer, the third insulating layer 110c may be a core layer, the fourth insulating layer 110d may be a lower insulating layer, and the fifth insulating layer 110e may be a lower cover insulating layer.

The third insulating layer 110c as the core layer may include a non-conductive material layer. For example, the third insulating layer 110c may include a reinforcing polymer or the like. The third insulating layer 110c may serve as a boundary layer dividing an upper portion and a lower portion of the package substrate 110.

A first wiring 120b may be formed on an upper surface of the third insulating layer 110c, a second wiring 120c may be formed on a lower surface of the third insulating layer 110c, and a via wiring 120a may penetrate the third insulating layer 110c to electrically connect the first wiring 120b as an upper conductive pattern and the second wiring 120c as a lower conductive pattern. The first wiring 120b and the second wiring 120c may be referred to as a first circuit layer and a second circuit layer stacked in a thickness direction from the upper surface 112 of the package substrate 110. For example, the first circuit layer and the second circuit layer may be vertically stacked. The wiring 120a, 120b and 120c may include, for example, metal materials such as copper, aluminum, etc. It will be understood that the arrangements and numbers of the insulating layers and the conductive patterns are illustrative and not necessarily limited thereto.

The plurality of upper substrate pads 130 may be provided on an upper surface of the second insulating layer 110b. For example, the plurality of upper substrate pads 130 may be disposed adjacent to the first insulating layer 110a in a lateral direction. The first insulating layer 110a may be formed on an upper surface of the second insulating layer 110b and exposes at least portions of the upper substrate pads 130.

The plurality of lower substrate pads 140 may be provided on a lower surface of the fourth insulating layer 110d. The fifth insulating layer 110e may be formed on a lower surface of the fourth insulating layer 110d and expose at least portions of the lower substrate pads 140.

As illustrated in FIG. 3, the package substrate 110 may include a first side portion S11 and a second side portion S12 extending in a direction parallel to a second direction (Y direction) and facing each other, and a third side portion S13 and a fourth side portion S14 extending in a direction parallel to a first direction (X direction) perpendicular to the second direction (Y direction) and facing each other.

The plurality of lower substrate pads 140 may include signal substrate pads 142 disposed in a middle region MR on the lower surface 114 of the package substrate 110 and ground substrate pads 144 disposed in an edge region ER surrounding the middle region MR. The signal substrate pads 142 may be arranged in an array formation in the middle region MR. The ground substrate pads 144 may be arranged in a line and spaced apart from each other along the edge region ER to surround the middle region MR.

The signal substrate pads 142 may be electrically connected to a data wiring or a power wiring among the wirings 120a, 120b and 120c. A data signal or a power signal may be transmitted through the signal substrate pads 142. The ground substrate pads 144 may be electrically connected to a ground wiring 122 among the wirings 120a, 120b and 120c. A ground signal may be transmitted through the ground substrate pads 144.

As illustrated in FIGS. 1 and 2, in example embodiments, the semiconductor chip 200 may be attached to the upper surface 112 of the package substrate 110 using an adhesive film 220 such as a die attach film (DAF). The semiconductor chip 200 may be attached to the package substrate 110 using the adhesive film 220 by a die attach process. A thickness of the adhesive film 220 may be within a range of 10 μm to 60 μm.

The semiconductor chip 200 may be disposed such that a second surface (inactive surface) 204, which is opposite to a first surface (active surface) 202 on which chip pads 210 are formed, faces the package substrate 110. The semiconductor chip 200 may be stacked on the package substrate 110 such that the first surface 202 on which the chip pads 210 are formed faces upward, towards the sealing member 240.

The semiconductor chip 200 may be a logic chip including logic circuits. The logic chip may be a controller that controls memory chips. The semiconductor chip 200 may be a processor chip such as ASIC or an application processor AP as a host such as CPU, GPU, or SOC.

Alternatively, the semiconductor chip 200 may include a memory chip including memory circuits. For example, the semiconductor chip 200 may include volatile memory devices such as SRAM devices or DRAM devices, and non-volatile memory devices such as flash memory devices, PRAM devices, MRAM devices or RRAM devices.

In these embodiments, one semiconductor chip 200 is disposed, but the present inventive concept is not necessarily limited thereto, and for example, a plurality of semiconductor chips 200 may be sequentially stacked on a package region PR of the package substrate 110.

The semiconductor chip 200 may be electrically connected to the package substrate 110 through bonding wires 230 that serve as the conductive connection members. The chip pads 210 of the semiconductor chip 200 may be connected to the upper substrate pads 130 on the upper surface 112 of the package substrate 110 by the bonding wires 230.

In some embodiments, the semiconductor chip 200 may be mounted on the package substrate 110 using a flip chip bonding method. The semiconductor chip 200 may be mounted on the package substrate 110 using conductive bumps. The semiconductor chip 200 may be mounted on the package substrate 110 such that the active surface on which the chip pads 210 are formed, that is, the first surface 202, faces the package substrate 110.

In this case, the conductive bumps may include micro bumps (uBump). The conductive bumps may be formed on the chip pads 210, and the conductive bumps may be interposed between the chip pads 210 of the semiconductor chip 200 and the upper substrate pads 130 of the package substrate 110. For example, the conductive bump may include solder bumps and/or pillar bumps.

The sealing member 240 may be provided on the package substrate 110 and cover the semiconductor chip 200. The sealing member 240 may include, for example, an epoxy mold compound (EMC). The sealing member 240 may include UV resin, polyurethane resin, silicone resin, silica filler, etc.

In example embodiments, the electromagnetic shielding member 400 may be provided on an upper surface and side surfaces of the semiconductor package 100. The electromagnetic shielding member 400 may include a plurality of stacked metal layers. The electromagnetic shielding member 400 may include a conductive material. For example, the conductive material may include metal such as copper, silver, stainless steel, etc. The electromagnetic shielding member 400 may be formed by a coating process, a spray process, a plating process, a deposition process, etc.

A bottom surface of the semiconductor package 100, that is, the bottom surface 114 of the package substrate 110, may be exposed and not covered by the electromagnetic shielding member 400. The plurality of electromagnetic shielding balls 320 may be disposed in a line and spaced apart from each other on the lower surface 114 of the package substrate 110, adjacent to a lower end portion of the electromagnetic shielding member 400.

Additionally, the electromagnetic shielding member 400 may contact a portion of the ground wiring 122 that is exposed from the side surface S12 of the package substrate 110. Accordingly, the electromagnetic shielding member 400 may be electrically connected to the ground substrate pads 144 through the ground wiring 122.

In example embodiments, the plurality of conductive connection members 300 may be disposed on the bottom surface of the semiconductor package 100 that is exposed by the lower end portion of the electromagnetic shielding member 400, that is, the bottom surface 114 of the package substrate 110. The plurality of conductive connection members 300 may include the plurality of signal connection balls 310 that are respectively disposed on the plurality of signal substrate pads 142 and the plurality of electromagnetic magnetic connection balls 310 that are respectively disposed on the plurality of ground substrate pads 144. Solder balls serving as the conductive connection members may be attached to the plurality of lower substrate pads 140 through a solder ball attach process. The conductive connection member 300 may include, for example, tin (Sn), indium (In), bismuth (Bi), antimony (Sb), copper (Cu), silver (Ag), zinc (Zn), lead (Pb), or alloys thereof.

As illustrated in FIGS. 3 and 4, the plurality of signal connection balls 310 may be arranged in an array formation on the middle region MR of the lower surface 114 of the package substrate 110. The plurality of electromagnetic shielding balls 320 may be arranged in a row and spaced apart from each other on the edge region ER surrounding the middle region MR along an edge of the lower surface 114 of the package 110.

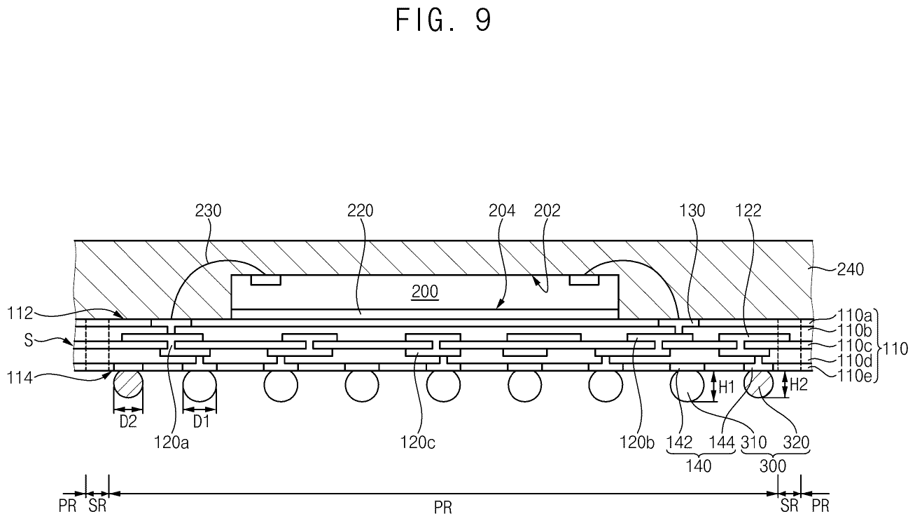

Each of the signal connection balls 310 may have a first diameter D1, and each of the electromagnetic shielding balls 320 may have a second diameter D2 that is smaller than the first diameter D1. The first diameter D1 may be within a range of 400 μm to 500 μm, and the second diameter D2 may be within a range of 200 μm to 400 μm. Each of the signal connection balls 310 may have a first height H1 (see FIG. 9) which is measured from the lower surface 114 of the package substrate 110 to the lowest points of the signal connection balls 310, and each of the electromagnetic shielding balls 320 may have a second height H2 (see FIG. 9) that is smaller than the first height H1, which is measured from the lower surface 114 of the package substrate 110 to the lowest points of the electromagnetic shielding balls 320.

At least portions of the electromagnetic shielding balls 320 may be arranged to overlap at least one side portion S11, S12, S13, S14 of the package substrate 110. A spacing distance L2, distance between the electromagnetic shielding balls, 320 may be within a range of 80 μm to 150 μm.

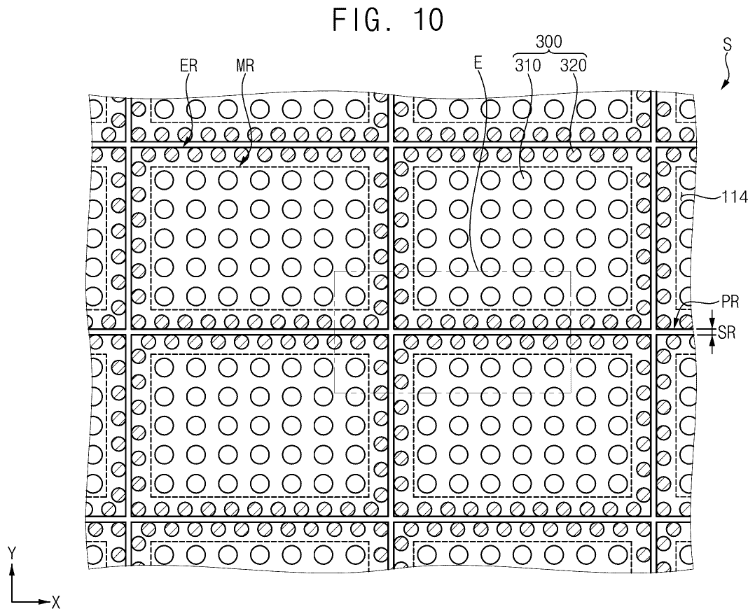

Accordingly, even if the edge region ER outside the area where the signal connection balls 310 are arranged is very small, the electromagnetic shielding balls 320 having relatively smaller diameters than the signal connection balls 310 may be arranged along a cutting region SR (see FIG. 10) to form an electromagnetic shielding fence on the lower surface 114 of the package substrate 110.

In example embodiments, the semiconductor package 100 may be mounted on the main board 20 via the plurality of conductive connection members 300. A plurality of conductive bumps as the conductive connection members 300 may be respectively disposed on the plurality of pads 30. The plurality of pads 30 may include the plurality of signal pads 32 and the plurality of ground pads 34. The plurality of signal connection balls 310 may be respectively disposed on the plurality of signal pads 32. The plurality of electromagnetic shielding balls 320 may be respectively disposed on the plurality of ground pads 34.

As illustrated in FIG. 2, in order to compensate for height differences between the electromagnetic shielding balls 320 and the signal connection balls 310, the plurality of signal pads 32 may have a non-solder mask defined (NSMD) type pad structure and the plurality of ground pads 34 may have a solder mask defined (SMD) type pad structure.

A diameter of each of the plurality of signal pads 32 may be smaller than a diameter of a first opening 44 of the protective layer 40 that exposes each of the signal pads 32. Accordingly, the signal pad 32 may be formed to be exposed through the first opening 44 of the protective layer 40. A diameter of each of the plurality of ground pads 34 may be greater than a diameter of a second opening 46 of the protective layer 40 that exposes each of the ground pads 34. Accordingly, a peripheral portion of the ground pad 34 may be covered by the protective layer 40, and a central portion of the ground pad 34 may be exposed from the second opening 46 of the protective layer 40.

After the semiconductor package 100 on which the plurality of conductive bumps 300 are formed is placed on the main board 20, a reflow process may be performed to bond the plurality of conductive bumps 300 to the plurality of pads 30 on the main board 20. At this time, a portion of the reflowed signal connection ball 310 may move into a space between the signal pad 32 and an inner wall of the first opening 44 of the protective layer 40, to thereby compensate the height differences between for the electromagnetic shielding balls 320 and the signal connection balls 310.

As mentioned above, the electronic device 10 may include the main board 20, the semiconductor package 100 disposed on the main board 20 and mounted via the plurality of conductive connection members 300, and the electromagnetic shielding member 400 covering the upper surface and the side surface of the semiconductor package 100. The plurality of conductive connection members 300 may include the plurality of signal connection balls 310 disposed in the middle region MR on the lower surface of the semiconductor package 100 exposed by the electromagnetic shielding member 400, that is, on the lower surface 114 of the package substrate 110 and having the first diameter D1, and the plurality of electromagnetic shielding balls 320 spaced apart from each other to surround the middle region MR along the edge of the lower surface of the semiconductor package 100 and having the second diameter D2 smaller than the first diameter D1.

Accordingly, even if the edge region ER excluding the area where the signal connection balls 310 are arranged is very small, the electromagnetic shielding balls 320 having relatively smaller diameters than the signal connection balls 310 may be arranged along the edge region to from the electromagnetic shielding fence on the lower surface 114 of the package substrate 110. Thus, even if there is no free space in the peripheral region of the lower surface of the semiconductor package 100, a ground ball fence may be formed to shield electromagnetic waves radiated through a gap between the semiconductor package 100 and the main board 20.

Hereinafter, a method of manufacturing the semiconductor package in FIG. 1 will be explained.

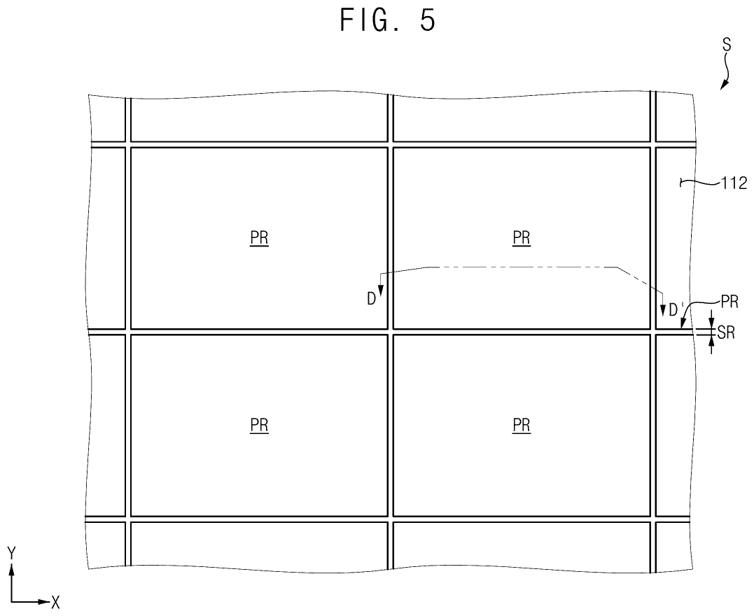

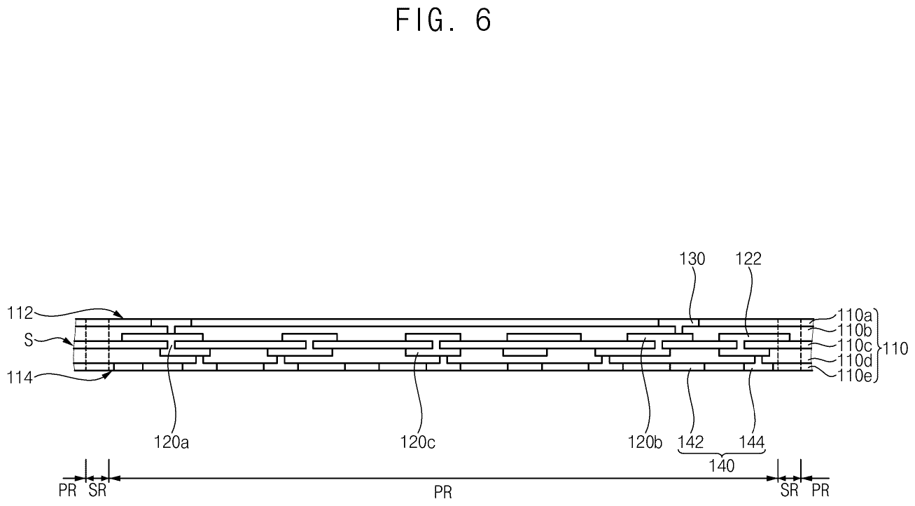

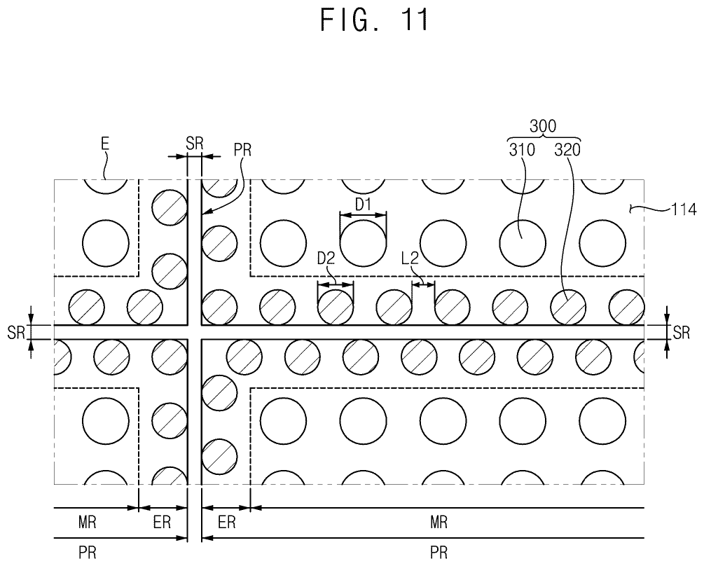

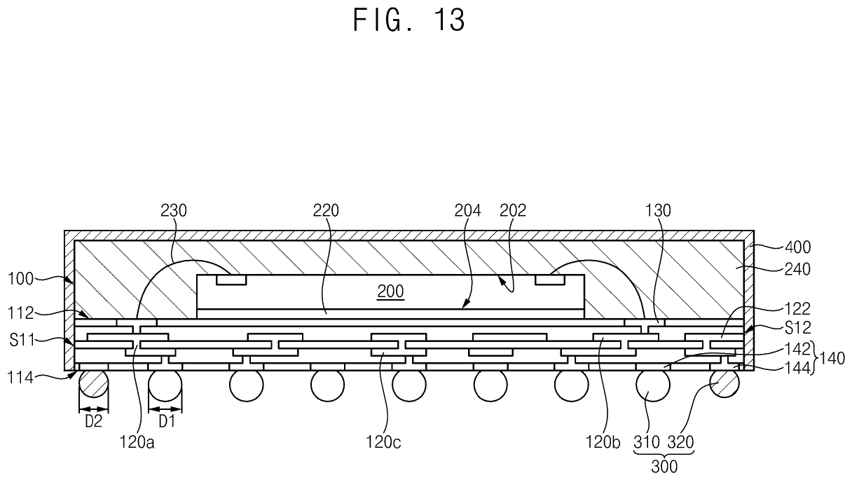

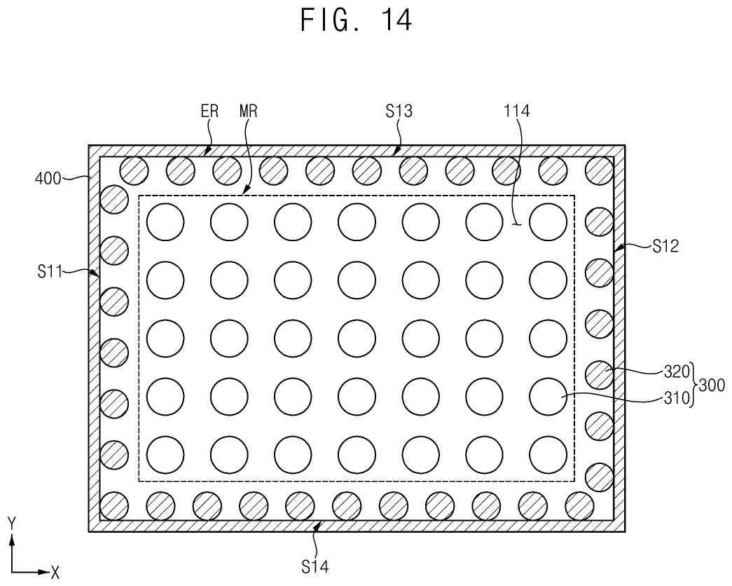

FIGS. 5, 6, 7, 8, 9, 10, 11, 12, 13, 14 and 15 are views illustrating a method of manufacturing an electronic device in accordance with example embodiments. FIG. 5 is a plan view illustrating a strip substrate on which semiconductor chips are to be mounted. FIGS. 6, 7, 8 and 9, 12, 13 and 15 are cross-sectional views illustrating a method of manufacturing an electronic device in accordance with example embodiments. FIG. 10 is a bottom view of FIG. 9. FIG. 11 is an enlarged bottom view illustrating portion ‘E’ in FIG. 10. FIG. 14 is a bottom view of FIG. 13. FIGS. 6 to 9, 12, 13 and 15 are cross-sectional views taken along the line D-D′ in FIG. 6.

Referring to FIGS. 5 and 6, a substrate S in which package substrates are formed may be provided.

In example embodiments, the substrate S may be a multilayer circuit substrate having an upper surface 112 and a lower surface 114 opposite to each other. The substrate S may be a strip substrate for manufacturing a semiconductor strip, such as a printed circuit board (PCB). The substrate S may include a printed circuit board (PCB), a flexible substrate, a tape substrate, etc. The substrate S may a multilayer circuit board having vias and various circuits therein.

As illustrated in FIG. 5, the substrate S may include a package region PR on which a semiconductor chip is to be mounted and a scribe lane region surrounding the package region PR, that is, a cutting region SR. As will be described later, after a plurality of semiconductor chips are respectively disposed on the package regions PR of the substrate S, the substrate S may be cut along the cutting region SR dividing the package region PR into individual package substrates. For example, tens to hundreds of semiconductor chips may be arranged in a matrix form on the substrate S.

As illustrated in FIG. 6, the substrate S may include a plurality of stacked insulating layers 110a, 110b, 110c, 110d and 110e and wirings 120a, 120b and 120c respectively provided in the insulating layers. Additionally, the substrate S may include a plurality of upper substrate pads 130 and a plurality of lower substrate pads 140.

In particular, the substrate S may include first to fifth insulating layers 110a, 110b, 110c, 110d and 110e sequentially stacked. The first insulating layer 110a may be an upper cover insulating layer, the second insulating layer 110b may be an upper insulating layer, the third insulating layer 110c may be a core layer, the fourth insulating layer 110d may be a lower insulating layer, and the fifth insulating layer 110e may be a lower cover insulating layer.

The third insulating layer 110c as the core layer may include a non-conductive material layer. The third insulating layer 110c may include a reinforcing polymer or the like. The third insulating layer 110c may serve as a boundary layer dividing an upper portion and a lower portion of the package substrate 110. For example, the upper portion of the package substrate 110 may include the first and second insulating layers 110a and 110b, and the lower portion of the package substrate 110 may include the fourth and the fifth insulating layers 110d and 110e. A first wiring 120b may be formed on an upper surface of the third insulating layer 110c, a second wiring 120c may be formed on a lower surface of the third insulating layer 110c, and a via wiring 120a may penetrate the third insulating layer 110c to electrically connect the first wiring 120b as an upper conductive pattern and the second wiring 120c as a lower conductive pattern. The first wiring 120b and the second wiring 120c may be referred to as a first circuit layer and a second circuit layer stacked in a thickness direction from the upper surface 112 of the package substrate 110. The wiring 120a, 120b and 120c may include metal materials such as copper, aluminum, etc. It will be understood that the arrangements and numbers of the insulating layers and the conductive patterns are illustrative and not necessarily limited thereto.

The plurality of upper substrate pads 130 may be provided on an upper surface of the second insulating layer 110b. The first insulating layer 110a may be formed on an upper surface of the second insulating layer 110b to expose at least portions of the upper substrate pads 130.

The plurality of lower substrate pads 140 may be provided on a lower surface of the fourth insulating layer 110d. The fifth insulating layer 110e may be formed on a lower surface of the fourth insulating layer 110d to expose at least portions of the lower substrate pads 140.

The insulating layers 110a, 110b, 110c, 110d and 110e may include an insulating material having a thermosetting resin such as epoxy resin or a thermoplastic resin such as polyimide. The insulating layers 110a, 110b, 110c, 110d and 110e may include a resin impregnated in a core material such as organic fiber (glass fiber), for example, a prepreg, FR-4, BT (Bismaleimide Triazine), etc.

In example embodiments, the plurality of lower substrate pads 140 may include signal substrate pads 142 disposed in a middle region of the package region PR and ground substrate pads 144 disposed in an edge region surrounding the middle region. The signal substrate pads 142 may be arranged in an array formation in the middle region. The ground substrate pads 144 may be arranged in a line and spaced apart from each other along the edge region to surround the middle region.

The signal substrate pads 142 may be electrically connected to a data wiring or a power wiring among the wirings 120a, 120b and 120c. A data signal or a power signal may be transmitted through the signal substrate pads 142. The ground substrate pads 144 may be electrically connected to a ground wiring 122 among the wirings 120a, 120b and 120c. A ground signal may be transmitted through the ground substrate pads 144.

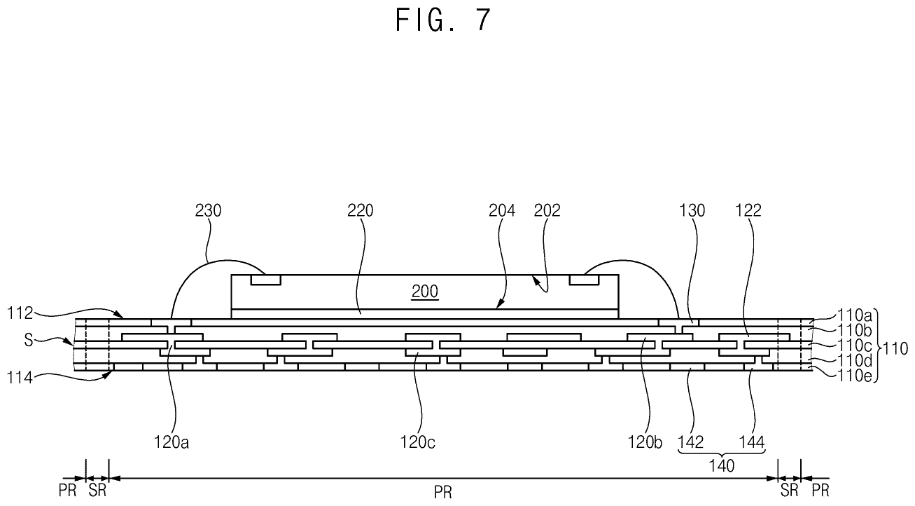

Referring to FIG. 7, at least one semiconductor chip 200 may be mounted on the substrate S.

In example embodiments, the semiconductor chip 200 may be attached to the package region PR of the package substrate 110 using an adhesive film 220. The semiconductor chip 200 may be attached to the package substrate 110 using the adhesive film 220 such as a die attach film (DAF) by a die attach process. A thickness of the adhesive film 220 may be within a range of 10 μm to 60 μm.

The semiconductor chip 200 may be disposed such that a second surface (inactive surface) 204, which is opposite to a first surface (active surface) 202 on which chip pads 210 are formed, faces the package substrate 110. The semiconductor chip 200 may be stacked on the package substrate 110 such that the first surface 202 on which the chip pads 210 are formed faces upward.

The semiconductor chip 200 may be a logic chip including logic circuits. The logic chip may be a controller that controls memory chips. The semiconductor chip 200 may be a processor chip such as ASIC or an application processor AP as a host such as CPU, GPU, or SOC.

In some embodiments, the semiconductor chip 200 may include a memory chip including memory circuits. For example, the semiconductor chip may include volatile memory devices such as SRAM devices or DRAM devices, and non-volatile memory devices such as flash memory devices, PRAM devices, MRAM devices or RRAM devices.

In these embodiments, one semiconductor chip 200 is disposed, but the present inventive concept is not necessarily limited thereto, and for example, a plurality of semiconductor chips 200 may be sequentially stacked on a package region MR of the package substrate 110.

Then, the semiconductor chip 200 may be electrically connected to the package substrate 110 through bonding wires 230 that serve as conductive connection members.

In example embodiments, a wire bonding process may be performed to connect the chip pads 210 of the semiconductor chip 200 to the upper substrate pads 130 on the upper surface 112 of the package substrate 110 using the bonding wires 230

In another embodiment, the semiconductor chip 200 may be mounted on the package substrate 110 using a flip chip bonding method. The semiconductor chip 200 may be mounted on the package substrate 110 using conductive bumps. The semiconductor chip 200 may be mounted on the package substrate 110 such that the active surface on which the chip pads 210 are formed, that is, the first surface 202, faces the package substrate 110.

In this case, the conductive bumps may include micro bumps (uBump). The conductive bumps may be formed on the chip pads 210, and the conductive bumps may be interposed between the chip pads 210 of the semiconductor chip 200 and the upper substrate pads 130 of the package substrate 110. The conductive bump may include solder bumps and/or pillar bumps.

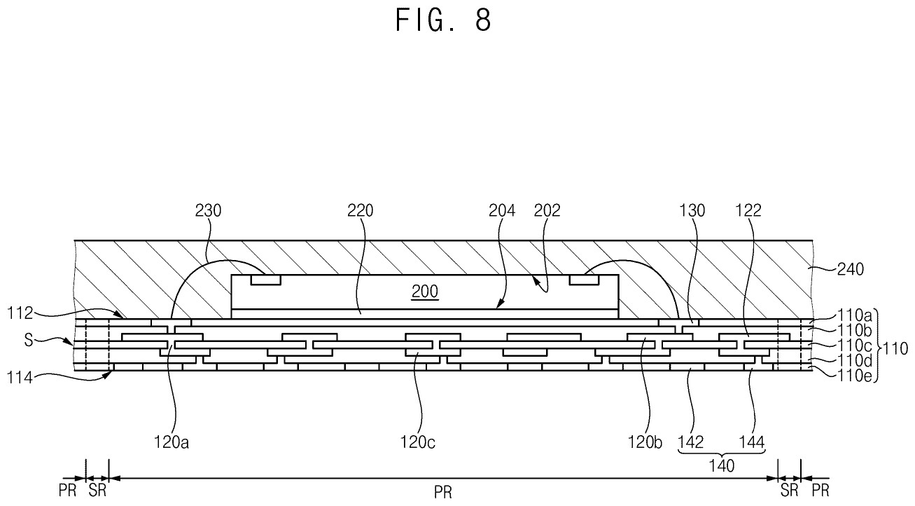

Referring to FIG. 8, a sealing member 240 may be formed on the substrate S and cover the semiconductor chip 200.

The sealing member 240 may include an epoxy mold compound (EMC). The sealing member 240 may include UV resin, polyurethane resin, silicone resin, silica filler, etc.

Referring to FIGS. 9 to 11, a plurality of conductive connection members 300 may be formed on the plurality of lower substrate pads 140 on the lower surface 114 of the package substrate 110. The plurality of conductive connection members 300 may include a plurality of signal connection balls 310 respectively disposed on the signal substrate pads 142 and a plurality of electromagnetic shielding balls 320 respectively disposed on the ground substrate pads 144.

In example embodiments, solder balls serving as the conductive connection members may be attached to the plurality of lower substrate pads 140 by a solder ball attach process. A solder ball attachment apparatus may include a body and a solder ball holding portion. The body may include an internal space in communication with an external vacuum forming device, and the solder ball holding portion may include a plurality of suction pockets in communication with the internal space and capable of selectively adsorbing solder balls, respectively. A vacuum may be provided to the suction pockets to adsorb the solder balls, and the vacuum may be removed from the suction pockets to attach the solder balls to the lower substrate pads 140 of the package substrate 110, respectively.

As illustrated in FIGS. 10 and 11, the plurality of signal connection balls 310 may be arranged in an array formation on the middle region MR of the lower surface 114 of the package substrate 110. The plurality of electromagnetic shielding balls 320 may be arranged in a row and spaced apart from each other on the edge region ER surrounding the middle region MR along an edge of the lower surface 114 of the package 110.

Each of the signal connection balls 310 may have a first diameter D1, and each of the electromagnetic shielding balls 320 may have a second diameter D2 that is smaller than the first diameter D1. The first diameter D1 may be within a range of 400 μm to 500 μm, and the second diameter D2 may be within a range of 200 μm to 400 μm. Each of the signal connection balls 310 may have a first height H1 which is measured from the lower surface 114 of the package substrate 110 to the lowest points of the signal connection balls 310, and each of the electromagnetic shielding balls 320 may have a second height H2 that is smaller than the first height H1, which is measured from the lower surface 114 of the package substrate 110 to the lowest points of the electromagnetic shielding balls 320.

At least portions of the electromagnetic shielding balls 320 may be arranged to overlap at least one side portion S11, S12, S13, S14 of the package substrate 110. The electromagnetic shielding balls 320 arranged on the package regions MR adjacent to each other along both sides of the cutting region SR may be arranged in a zigzag shape. A width of the cutting region SR to be removed by a sawing apparatus may be 120 μm.

A spacing distance L2, distance between the electromagnetic shielding balls 320, may be within a range of 80 μm to 150 μm. Since a minimum distance between the neighboring adsorption pockets is required for arranging the adsorption pockets, the spacing distance L2 between the electromagnetic shielding balls 320 may be determined in consideration of the minimum distance between the neighboring adsorption pockets.

Accordingly, even if the edge region ER outside the region where the signal connection balls 310 are arranged is very small, the electromagnetic shielding balls 320 having relatively smaller diameters than the signal connection balls 310 may be arranged along the cutting region SR and form an electromagnetic shielding fence on the lower surface 114 of the package substrate 110.

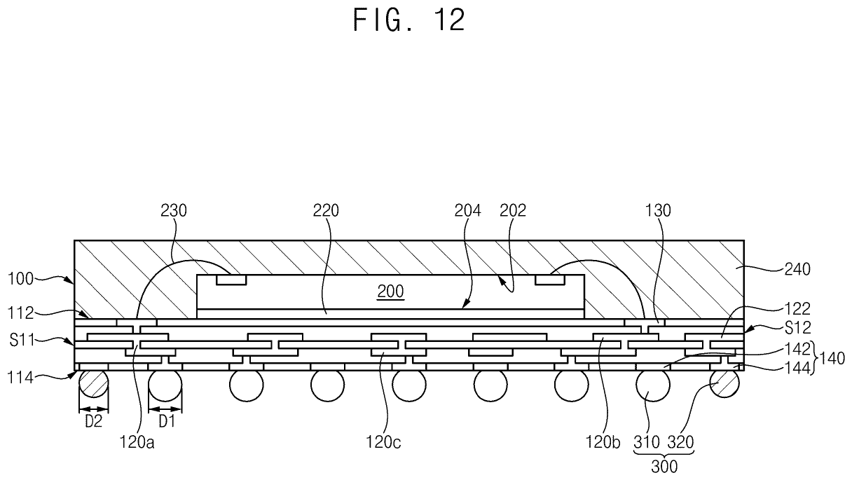

Referring to FIGS. 12 to 14, the substrate S may be cut along the cutting region SR into individual semiconductor package 100, and an electromagnetic shielding member 400 may be formed to cover an upper surface and side surfaces of the semiconductor package 100.

As illustrated in FIG. 12, the cutting region SR of the substrate S may be removed using a sawing apparatus such as a blade. Thus, the substrate S may be separated into individual semiconductor packages 100. At this time, a portion of the ground wiring 122 may be exposed from the side surface S12 of the package substrate 110.

As illustrated in FIGS. 13 and 14, the electromagnetic shielding member 400 may be formed by stacking metal layers on the upper surface and the side surfaces of the semiconductor package 100. The electromagnetic shielding member 400 may include a plurality of stacked metal layers. The electromagnetic shielding member 400 may include a conductive material such as copper, silver, stainless steel, etc. The electromagnetic shielding member 400 may be formed by, for example, a coating process, a spray process, a plating process, a deposition process, etc.

A bottom surface of the semiconductor package 100, that is, a bottom surface 114 of the package substrate 110, may be exposed by a lower end portion of the electromagnetic shielding member 400. A plurality of electromagnetic shielding balls 320 arranged in a horizontal line and spaced apart from each other may be disposed on the lower surface 114 of the package substrate 110, adjacent to the lower end portion of the electromagnetic shielding member 400.

Additionally, the electromagnetic shielding member 400 may contact a portion of the ground wiring 122 exposed from the side surface S12 of the package substrate 110. Accordingly, the electromagnetic shielding member 400 may be electrically connected to the electromagnetic shielding balls 320 through the ground wiring 122 and the ground substrate pads 144.

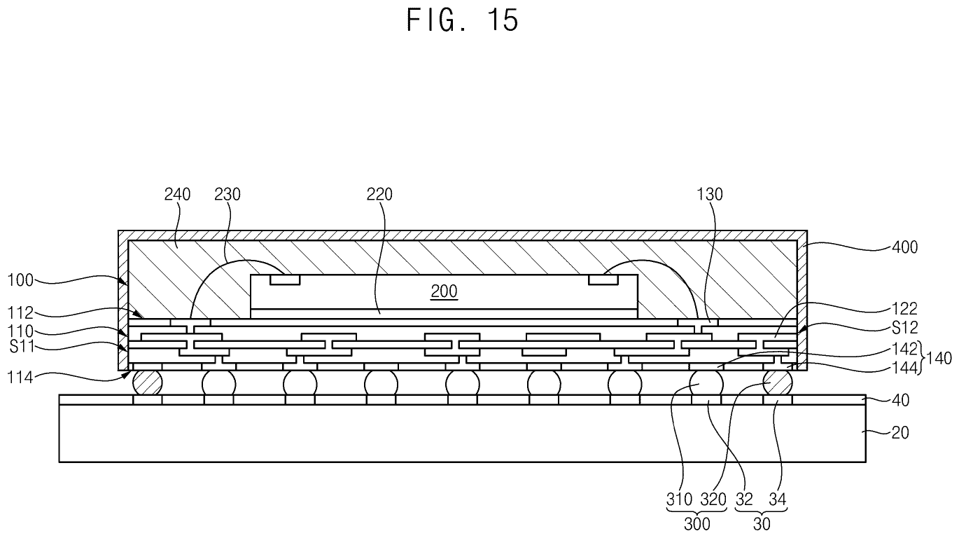

Referring to FIG. 15, the semiconductor package 100 may be mounted on a main board 20 via the plurality of conductive connection members 300.

In example embodiments, the main board 20 may be a multilayer circuit board having an upper surface and a lower surface opposite to each other. For example, the main board 20 may be a printed circuit board (PCB). The printed circuit board may be a multilayer circuit board having vias and various circuits therein.

The main board 20 may include a plurality of pads 30 on the upper surface thereof and a protective layer 40 having openings 42 that expose the plurality of pads 30 respectively. For example, the protective layer 40 may be disposed adjacent to the plurality of pads 30 in a lateral direction. The plurality of pads 30 may include a plurality of signal pads 32 and a plurality of ground pads 34. The plurality of pads 30 may be electrically connected to various circuit wires in the main board 20. The ground pads 34 may be electrically connected to a separate ground circuit formed in the main board 20.

The plurality of conductive connection members 300 may be disposed on the plurality of pads 30. The plurality of signal connection balls 310 may be respectively disposed on the plurality of signal pads 32. The plurality of electromagnetic magnetic connection balls 310 may be respectively disposed on the plurality of ground pads 34.

In example embodiments, in order to compensate for height differences between the electromagnetic shielding balls 320 and the signal connection balls 310, the plurality of signal pads 32 may have a non-solder mask defined (NSMD) type pad structure and the plurality of ground pads 34 may have a solder mask defined (SMD) type pad structure.

A diameter of each of the plurality of signal pads 32 may be smaller than a diameter of a first opening 44 of the protective layer 40 that exposes each of the signal pads 32. Accordingly, the signal pad 32 may be formed to be exposed through the first opening 44 of the protective layer 40. A diameter of each of the plurality of ground pads 34 may be greater than a diameter of a second opening 46 of the protective layer 40 that exposes each of the ground pads 34. Accordingly, a peripheral portion of the ground pad 34 may be covered by the protective layer 40, and a central portion of the ground pad 34 may be exposed from the second opening 46 of the protective layer 40.

After the semiconductor package 100 on which the plurality of conductive connection members 300 are formed is placed on the main board 20, a reflow process may be performed to bond the plurality of conductive bumps 300 to the plurality of pads 30 on the main board 20. At this time, a portion of the reflowed signal connection ball 310 may move into a space between the signal pad 32 and an inner wall of the first opening 44 of the protective layer 40, to thereby compensate the height differences between for the electromagnetic shielding balls 320 and the signal connection balls 310.

The plurality of conductive connection members 300 may be bonded to the plurality of pads 30 and complete the electronic device 10 of FIG. 1.

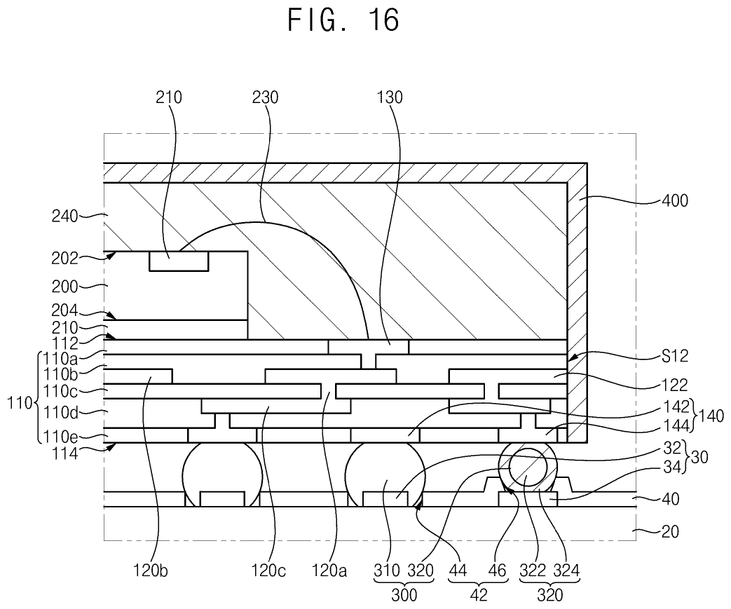

FIG. 16 is a cross-sectional view illustrating an electronic device in accordance with example embodiments. FIG. 16 is an enlarged cross-sectional view illustrating portion ‘A’ in

FIG. 1. The electronic device may be substantially the same as or similar to the electronic device described with reference to FIGS. 1 to 4 except for configurations of electromagnetic shielding balls. Thus, same reference numerals will be used to refer to the same or like elements and any further repetitive explanation concerning the above elements will be omitted.

Referring to FIG. 16, electromagnetic shielding balls 320 may include core balls. For example, the electromagnetic shielding ball 320 may include a core 322 and a solder layer 324 covering the core 322. The core 322 may have a spherical or elliptical spherical shape. The core 322 may include a material different from the solder layer 322. For example, the core 322 may include a metal such as copper (Cu) or polymer material. For example, the solder layer 324 may include tin (Sn), indium (In), bismuth (Bi), antimony (Sb), copper (Cu), silver (Ag), zinc (Zn), lead (Pb), or an alloy thereof.

A diameter of the core 322 may be within a range of 25 μm to 250 μm. Additionally, the core 322 may have a first melting point, and the solder layer 324 may have a second melting point that is lower than the first melting point.

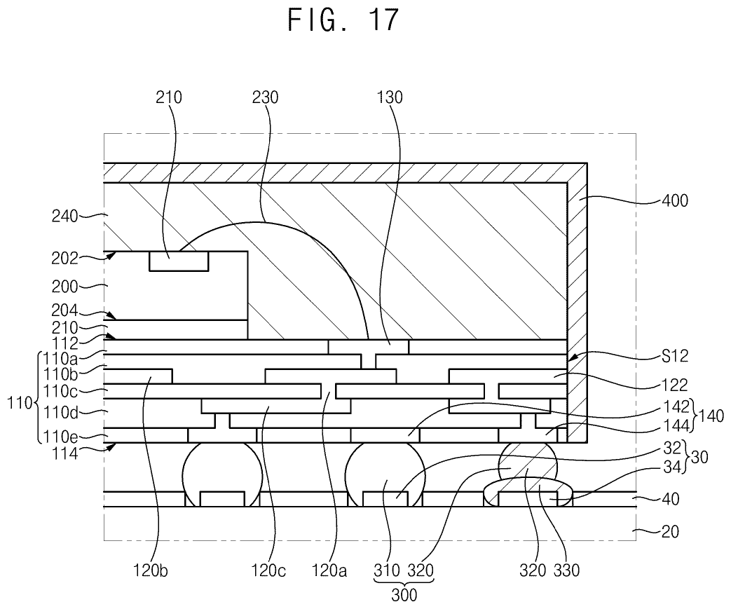

FIG. 17 is a cross-sectional view illustrating an electronic device in accordance with example embodiments. FIG. 17 is an enlarged cross-sectional view illustrating portion ‘A’ in FIG. 1. The electronic device may be substantially the same as or similar to the electronic device described with reference to FIGS. 1 to 4 except for additional solder-on pads. Thus, same reference numerals will be used to refer to the same or like elements and any further repetitive explanation concerning the above elements will be omitted.

Referring to FIG. 17, a main board 30 may further include solder-on pads (SOPs) 330 respectively disposed on a plurality of ground pads 34. The SOPs may at least partially cover each of the plurality of ground pads 32. A plurality of electromagnetic shielding balls 320 may be respectively disposed on the solder-on-pads 330. The solder-on pad 330 may include tin (Sn), indium (In), bismuth (Bi), antimony (Sb), copper (Cu), silver (Ag), zinc (Zn), lead (Pb), or alloys thereof.

Since the electromagnetic shielding balls 320 are respectively disposed on the solder- on pads 330, height differences between the electromagnetic shielding balls 320 and the signal connection balls 310 may be compensated.

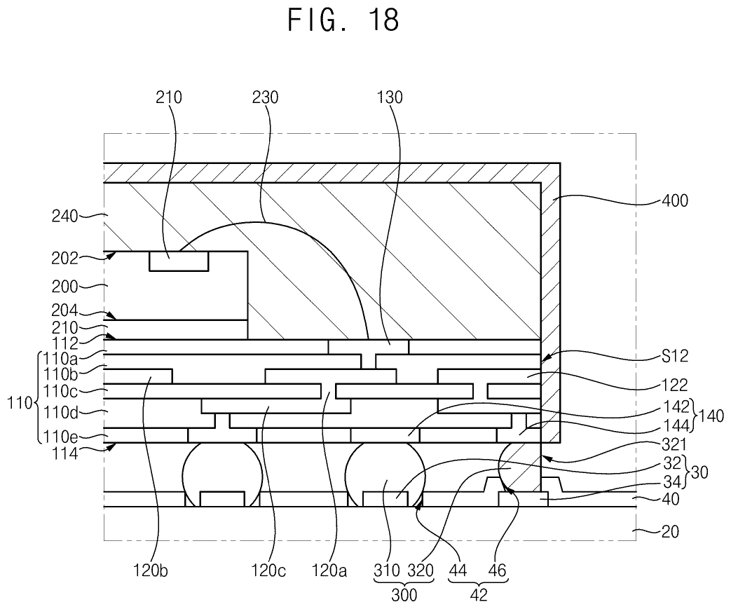

FIG. 18 is a cross-sectional view illustrating an electronic device in accordance with example embodiments. FIG. 18 is an enlarged cross-sectional view illustrating portion ‘A’ in FIG. 1. The electronic device may be substantially the same as or similar to the electronic device described with reference to FIGS. 1 to 4 except for arrangements and shapes of electromagnetic shielding balls. Thus, same reference numerals will be used to refer to the same or like elements and any further repetitive explanation concerning the above elements will be omitted.

Referring to FIG. 18, each of electromagnetic shielding balls 320 may have a cutting surface 321. The cutting surface 321 may be located on the same plane as one side surface S12 of a package substrate 110.

Hereinafter, a method of forming electromagnetic shielding balls of FIG. 18 will be described.

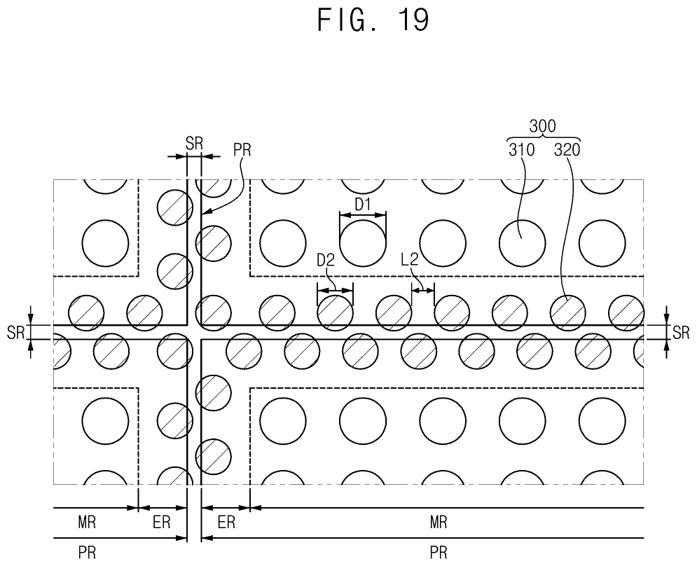

FIG. 19 is a bottom view illustrating a plurality of conductive connection members on a bottom surface of a semiconductor package. FIG. 19 is an enlarged bottom view illustrating portion ‘E’ in FIG. 10.

First, the same as or similar to the processes described with reference to FIGS. 5 to 8 may be performed to form a sealing member 240 on an upper surface 112 of a package substrate 110 and cover a semiconductor chip 200, and a plurality of conductive connection members 300 may be formed on a plurality of lower substrate pads 140 on a lower surface 114 of the package substrate 110.

Referring to FIG. 19, the electromagnetic shielding balls 320 may be formed such that at least portions of the electromagnetic shielding balls 320 are arranged to be located within a cutting region SR. The electromagnetic shielding balls 320 arranged on neighboring package regions MR along the cutting region SR may be arranged in a zigzag shape. A spacing distance L2 between the electromagnetic shielding balls 320 may be within a range of 80 μm to 150 μm.

Then, the same as or similar to the processes described with reference to FIG. 12 may be performed to cut the substrate S along the cutting region SR to form an individual semiconductor package 100.

The cutting region SR of the substrate S may be removed using a sawing apparatus such as a blade, laser, etc. At this time, the at least portions of the electromagnetic shielding balls 320 located in the cutting region SR may be removed, and each of the electromagnetic shielding balls 320 may have a cutting surface 321 (see FIG. 18).

The semiconductor package 100 of the electronic device may include semiconductor devices such as logic devices or memory devices. The semiconductor package 100 may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings of the present invention. Accordingly, all such modifications are intended to be included within the scope of example embodiments as set forth in the claims.

What is claimed is:

1. An electronic device, comprising:
a main board;
a semiconductor package disposed on the main board and mounted via a plurality of conductive connection members; and
an electromagnetic shielding member covering an upper surface and side surfaces of the semiconductor package,
wherein the plurality of conductive connection members includes:
a plurality of signal connection balls disposed on a middle region of a lower surface of the semiconductor package and having a first diameter; and
a plurality of electromagnetic shielding balls spaced apart from each other along an edge of the lower surface of the semiconductor package, the electromagnetic shielding balls surrounding the middle region and having a second diameter smaller than the first diameter.

2. The electronic device of claim 1, wherein the semiconductor package includes:
a package substrate having an upper surface and a lower surface and having signal substrate pads and ground substrate pads on the lower surface of the package substrate;
a semiconductor chip mounted on the upper surface of the package substrate; and
a sealing member covering the semiconductor chip.

3. The electronic device of claim 2, wherein the plurality of signal connection balls are disposed on the signal substrate pads, and the plurality of electromagnetic shielding balls are disposed on the ground substrate pads.

4. The electronic device of claim 2, wherein the package substrate includes a ground wiring, and a portion of the ground wiring is exposed from a side surface of the package substrate and is in contact with the electromagnetic shielding member.

5. The electronic device of claim 1, wherein at least portions of the plurality of electromagnetic shielding balls to overlap the side surfaces of the semiconductor package.

6. The electronic device of claim 1, wherein the first diameter is 400 μm to 500 μm, and the second diameter is 200 μm to 400 μm.

7. The electronic device of claim 1, wherein a distance between adjacent electromagnetic shielding balls is 80 μm to 150 μm.

8. The electronic device of claim 1, wherein the main board includes a plurality of signal pads on which the plurality of signal connection balls are disposed, a plurality of ground pads on which the plurality of electromagnetic shielding balls are disposed, and a protective layer having openings that expose the plurality of signal pads and the plurality of ground pads, and
wherein a diameter of each of the plurality of signal pads is smaller than a diameter of the opening of the protective layer, and a diameter of each of the plurality of ground pads is greater than the diameter of the opening of the protective layer.

9. The electronic device of claim 1, wherein each of the plurality of electromagnetic shielding balls includes a core ball that includes a core and a solder layer covering the core.

10. The electronic device of claim 1, wherein the main board includes a plurality of ground pads and solder-on pads disposed on the plurality of ground pads, and wherein the plurality of electromagnetic shielding balls are disposed on the solder-on pads.

11. An electronic device, comprising:
a main board having a plurality of signal pads and a plurality of ground pads;
a semiconductor package disposed on the main board, the semiconductor package including a package substrate having signal substrate pads disposed in a middle region on a lower surface of the package substrate and ground substrate pads disposed in an edge region surrounding the middle region, a semiconductor chip mounted on an upper surface of the package substrate, and a sealing member covering the semiconductor chip;
an electromagnetic shielding member covering an upper surface and side surfaces of the semiconductor package;
a plurality of signal connection balls disposed between the plurality of signal pads and the signal substrate pads and having a first diameter; and
a plurality of electromagnetic shielding balls disposed between the plurality of ground pads and the ground substrate pads and having a second diameter smaller than the first diameter.

12. The electronic device of claim 11, wherein the plurality of electromagnetic shielding balls are arranged in a line and spaced apart from each other along an edge of the package substrate.

13. The electronic device of claim 11, wherein at least portions of the plurality of electromagnetic shielding balls to overlap a side surface of the package substrate.

14. The electronic device of claim 11, wherein the package substrate includes a ground wiring therein, and a portion of the ground wiring is exposed from a side surface of the package substrate and is in contact with the electromagnetic shielding member.

15. The electronic device of claim 11, wherein the first diameter is 400 μm to 500 μm, and the second diameter is 200 μm to 400 μm.

16. The electronic device of claim 11, wherein a distance between neighboring electromagnetic shielding balls is 80 μm to 150 μm.

17. The electronic device of claim 11, wherein the main board includes a protective layer having openings that expose the plurality of signal pads and the plurality of ground pads, and a diameter of each of the plurality of signal pads is smaller than a diameter of the opening of the protective layer, and a diameter of each of the plurality of ground pads is greater than the diameter of the opening of the protective layer.

18. The electronic device of claim 11, wherein each of the plurality of electromagnetic shielding balls includes a core ball that includes a core and a solder layer covering the core.

19. The electronic device of claim 11, wherein the main board further includes solder-on pads disposed on each of the plurality of ground pads, wherein the plurality of electromagnetic shielding balls are disposed on the solder-on pads.

20. An electronic device, comprising:
a main board;
a semiconductor package disposed on the main board;
an electromagnetic shielding member covering an upper surface and side surfaces of the semiconductor package;
a plurality of signal connection balls disposed between the main board and the semiconductor package, disposed on a middle region of a lower surface of the semiconductor package, and having a first diameter; and
a plurality of electromagnetic shielding balls disposed between the main board and the semiconductor package, spaced apart from each other along an edge of the lower surface of the semiconductor package to surround the middle region, and having a second diameter smaller than the first diameter,
wherein the first diameter is 400 μm to 500 μm, and the second diameter is 200 μm to 400 μm, and
wherein a distance between neighboring electromagnetic shielding balls is 80 μm to 150 μm.
